(19) United States
(12) Patent Application Publication
(10) Pub. No.: US 2020/0312735 A1
(43) Pub. Date: Oct. 1, 2020

(54) COOLING OF ELECTRONIC DEVICES

(71) Applicant: STMicroelectronics (Grenoble 2) SAS, Grenoble (FR)

(72) Inventors: Romain COFFY, Voiron (FR); Alexandre COULLOMB, Apprieu (FR); Olivier FRANIATTE, Grenoble (FR)

(73) Assignee: STMicroelectronics (Grenoble 2) SAS, Grenoble (FR)

(21) Appl. No.: 16/829,210

(22) Filed: Mar. 25, 2020

(30) Foreign Application Priority Data
Mar. 28, 2019 (FR) 1903259

(51) Int. Cl. H01L 23/367; H01L 21/48; H01L 23/373; H01L 23/49

(52) U.S. Cl. CPC H01L 23/367; H01L 21/4871; H01L 23/49; H01L 23/3736; H01L 21/4867

(57) ABSTRACT

A substrate includes a through cavity. A heat sink is mounted so as to close one end of the through cavity. An integrated circuit (IC) chip is also mounted in the cavity. Conductive wires provide an electrical connection between pads on an upper surface of the IC chip and metallizations on the substrate. The mounted heat sink is positioned within the substrate in one implementation and positioned mounted to a back surface of the substrate in another implementation.

### PRIORITY CLAIM

This application claims the priority benefit of French Application for Patent No. 1903259, filed on Mar. 28, 2019, the content of which is hereby incorporated by reference in its entirety to the maximum extent allowable by law.

### TECHNICAL FIELD

The present disclosure generally concerns electronic devices and, more particularly, the cooling of electronic integrated circuit (IC) chips.

### BACKGROUND

Many techniques for cooling electronic integrated circuit (IC) chips once assembled in a package are known. For example, thermal vias crossing the substrate to which the IC chip is mounted are used to thermally contact a heat sink arranged under the substrate.

There is a need to improve the cooling of electronic IC chips, especially as such IC chips are becoming smaller and smaller and dissipating more and more power. There is further a need in the art to overcome all or part of the disadvantages of known devices for cooling electronic IC chips.

### SUMMARY

An embodiment provides an electronic device, comprising: a substrate comprising at least one cavity; a heat sink closing one end of the cavity; an integrated circuit (IC) chip, in said cavity; and one or a plurality of conductive wires of connection between a surface of the IC chip and the substrate.

An embodiment provides an method for forming an electronic device, comprising at least the steps of: etching a cavity in a substrate; arranging a heat sink to close one end of the cavity; arranging an integrated circuit (IC) chip in the cavity of the substrate; and connecting the IC chip to the substrate by conductive wires.

According to an embodiment, the device comprises a material for bonding the IC chip to the substrate and/or to the heat sink.

According to an embodiment, the bonding material is thermal paste.

According to an embodiment, the bonding material is solder paste.

According to an embodiment, at least a portion of the bonding material fills a space between the cavity walls and the IC chip.

According to an embodiment, at least a portion of the bonding material is between the IC chip and the heat sink.

According to an embodiment, the heat sink is embedded in the substrate so that the surface of the device is planar on the side of the cavity closed by the heat sink.

According to an embodiment, the heat sink is external to the substrate.

According to an embodiment, the heat sink is made of copper, optionally coated with a protection layer made of an alloy of nickel and of gold.

According to an embodiment, the cavity has a shoulder.

According to an embodiment, the shoulder receives the heat sink.

According to an embodiment, the shoulder is open on the side opposite to the heat sink.

According to an embodiment, the method comprises at least the successive steps of: depositing a film on a surface of the substrate to cover one end of the cavity; depositing the IC chip into the cavity on the film; depositing a bonding material in a space between the walls of the cavity and the IC chip; removing the film; and bonding the heat sink under the IC chip.

### BRIEF DESCRIPTION OF THE DRAWINGS

The foregoing and other features and advantages will be discussed in detail in the following non-limiting description of specific embodiments in connection with the accompanying drawings, wherein:

FIG. 1 is a simplified cross-section view of an embodiment of an electronic device comprising a heat sink;

FIG. 2 is a simplified cross-section view of another embodiment of an electronic device comprising a heat sink;

FIGS. 3A-3D show simplified cross-section views illustrating steps of implementation of a method of forming the electronic device of FIG. 1; and

FIGS. 4A-4E show simplified cross-section views illustrating steps of implementation of a method of forming the electronic device of FIG. 2.

### DETAILED DESCRIPTION

The same elements have been designated with the same reference numerals in the different drawings. In particular, the structural and/or functional elements common to the different embodiments may be designated with the same reference numerals and may have identical structural, dimensional, and material properties.

For clarity, only those steps and elements which are useful to the understanding of the described embodiments have been shown and are detailed.

Throughout the present disclosure, the term “connected” is used to designate a direct electrical connection between circuit elements with no intermediate elements other than conductors, whereas the term “coupled” is used to designate an electrical connection between circuit elements that may be direct, or may be via one or more other elements.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., unless otherwise specified, it is referred to the orientation of the drawings.

The terms “about”, “approximately”, “substantially”, and “in the order of” are used herein to designate a tolerance of plus or minus 10%, preferably of plus or minus 5%, of the value in question.

A usual solution to dissipate the heat of an electronic integrated circuit (IC) chip connected by wires to a substrate comprises directly propagating the heat in the substrate. Such a solution however requires increasing the thermal resistance of the substrate, and thus the thickness thereof. However, increasing the thermal resistances results in that it keeps more heat, which eventually adversely affects the general heat dissipation capacity of the device. This further goes against the desire to decrease the bulk of the device. Another known solution comprises dissipating the heat by means of thermal vias integrated to the substrate. Such a solution is however complex to implement since its efficiency in terms of dissipation is linked to the density of vias in the substrate.

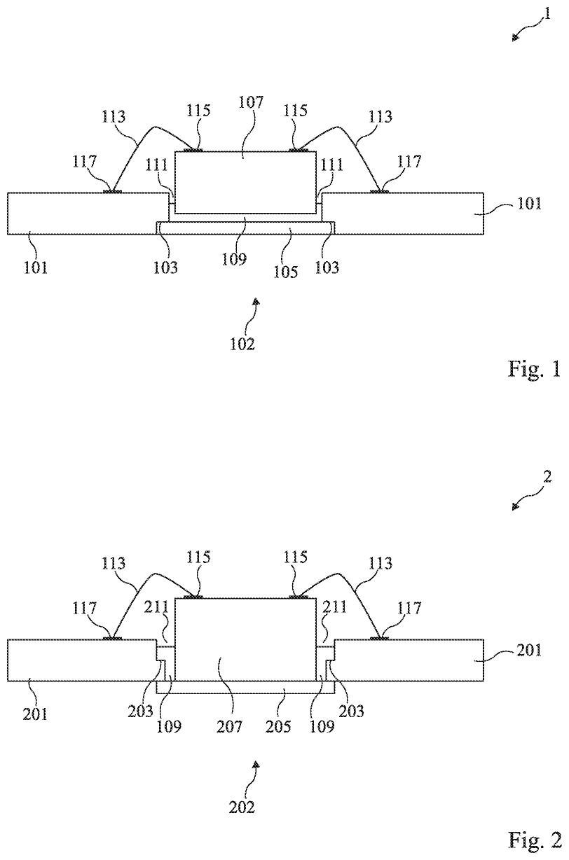

FIG. 1 is a simplified cross-section view of an embodiment of an electronic device 1 comprising a heat sink.

Device 1 comprises a substrate or support 101 comprising a cavity 102. Cavity 102 thoroughly crosses through the substrate 101 from its upper surface to its rear surface. Cavity 102 thus comprises an opening in the upper surface, or front side, of substrate 101, and another opening in the rear surface, or back side. Cavity 102 further comprises a shoulder 103, so that the surface area of the opening in the lower surface of substrate 101 is larger than that of the opening in the upper surface. Shoulder 103 extends from the lower surface of the substrate along part of the height of the cavity, for example, along at least half the height of the cavity.

A heat sink 105 is embedded in the lower portion of cavity 102. Heat sink 105 thus closes the lower end of cavity 102. The depth of the peripheral groove on the back side of the cavity, defined by shoulder 103, is selected according to the thickness of heat sink 105 or conversely, so that the latter is integrally housed in cavity 102 without protruding from the back side of substrate 101 (i.e., the rear surface of the substrate 101 and rear surface of the heat sink 105 are co-planar). The lower surface of device 1 is thus planar on the side of cavity 102 closed by heat sink 105. Heat sink 105 is, for example, made of metal, preferably of copper, possibly coated with a protection layer made of a nickel and gold alloy (NiAu).

Device 1 also comprises an electronic integrated circuit (IC) chip 107 above heat sink 105. At least a portion of IC chip 107 is located in cavity 102.

A bonding material 109 bonds IC chip 107 to substrate 101 and to heat sink 105. The material is present between IC chip 107 and heat sink 105. The material also fills at least a portion of a space 111, between IC chip 107 and the wall of cavity 102.

Bonding material 109 is, for example, solder paste or preferably thermal paste. In the case of solder paste, once the latter is arranged in cavity 102, the device is heated to melt the paste and favor the homogeneous distribution thereof under IC chip 107 and in space 111. The bonding is then obtained once the assembly has cooled down, under the effect of the hardening of the material. In the case of thermal paste, once the latter is arranged in cavity 102, the device is heated up to a temperature smaller than the melting temperatures of a solder or brazing paste. The bonding function is obtained after curing of the paste. Thermal pastes are advantageous due to the smaller required temperature, thus decreasing the power cost of the device manufacturing. Thermal pastes further have the advantage of providing a wider selection of thermal coefficients than solder pastes.

Conductive wires 113 connect IC chip 107 to substrate 101. Conductive wires 113 are used to connect contacts or connection pads 115 located on a surface of IC chip 107 to metallizations 117 located on the upper surface of the substrate. Two assemblies of conductive wires 113, connection pads 115, and metallizations 117 are shown in FIG. 1. In practice, a larger number of wires is generally used.

FIG. 1 shows an assembly of cavity 102, heat sink 105, and electronic IC chip 107. As a variation, a plurality of cavities and/or IC chips and/or heat sinks may be provided in a same device. In particular, a same cavity may contain a plurality of IC chips.

FIG. 2 is a simplified cross-section view of another embodiment of an electronic device 2 comprising a heat sink.

Device 2 comprises a substrate or support 201 comprising a cavity 202. Cavity 202 thoroughly crosses substrate 201. Cavity 202 thus comprises an opening in the upper surface, or front side, of substrate 201, and another opening in the lower surface, or back side. Cavity 202 comprises a shoulder 203, so that the surface of the opening in the upper surface of substrate 201 is larger than that of the opening in the lower surface. Shoulder 203 extends, from the upper surface of the substrate, along part of the height of cavity 202, for example, along more than half the height of the cavity.

As compared with device 1, described in relation with FIG. 1, device 2 comprises a heat sink 205 under substrate 201. Heat sink 205 is thus external to substrate 201. The dimensions of heat sink 205, in particular the dimensions of its upper surface, are selected to enable the heat sink to cover, or close, the lower end of cavity 202. The upper surface of the heat sink thus has a surface area greater than that of the opening for cavity 202 at the lower surface of the substrate. Heat sink 205 is, for example, made of metal, preferably of copper, possibly coated with a protection layer made of a nickel and gold alloy (NiAu).

Device 2 also comprises an electronic integrated circuit (IC) chip 207 on heat sink 205. At least a portion of IC chip 207 is located in cavity 202. As a variation, a material increasing the thermal conductivity between the lower surface of electronic IC chip 207 and heat sink 205, for example, thermal paste or thermal paste, is present between IC chip 207 and heat sink 205.

A bonding material 109 bonds IC chip 207 to substrate 201. The material is, for example, solder paste or preferably thermal paste. The material fills at least a portion of a space 211, between IC chip 207 and the walls of cavity 202.

As the surface area of the opening of cavity 202 is larger at the upper surface of substrate 201 than at the lower surface, the distance between IC chip 207 and the wall of cavity 202 is larger at the level of the upper portion of space 211 than in the lower portion of space 211. The distance at the level of the upper portion, defined by shoulder 203, is selected to ease the filling of space 211 with a bonding material 109.

As a variation, cavity 202 may take any other shape, for example, tapered, enabling to receive IC chip 207 and having an opening surface area larger at the upper surface of substrate 201 than at the lower surface. This variation with a taper shape for the cavity also applies to the cavity 102 for the embodiment of FIG. 1.

Similarly to the embodiment described in relation with FIG. 1, conductive wires 113 connect IC chip 207 to substrate 201. Conductive wires 113 are used to connect contacts or connection pads 115 located on a surface of IC chip 207 to metallizations 117 located on the upper surface of substrate 201. As for FIG. 1, any number of conductive wires 113, connection pads 115, and metallizations 117 may be provided.

FIG. 2 shows an assembly of cavity 202, heat sink 205, and electronic IC chip 207. As a variation, a plurality of cavities and/or IC chips and/or heat sinks may be provided in a same device. In particular, a same heat sink may close a plurality of cavities.

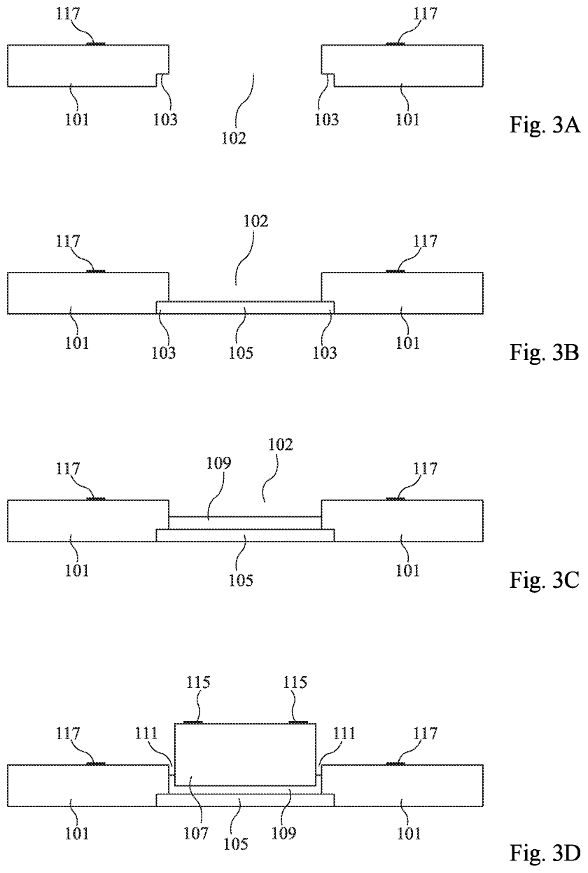

FIGS. 3A-3D show simplified transverse cross-section views illustrating steps of implementation of a method of forming the electronic device of FIG. 1.

FIG. 3A illustrates a substrate 101, obtained after a step of etching a cavity 102 comprising a shoulder 103.

The step of etching cavity 102 and its shoulder 103 is comprised of two etching sub-steps.

A first etching sub-step, carried out by using a first mask, removes material from the entire thickness of substrate 101. A second etching sub-step removes material from the lower surface of the substrate across a portion of the thickness of substrate 101. The second etching uses a second mask comprising an opening larger than that of the first mask. In other words, the first etching forms the cavity while the second etching forms shoulder 103. As a variation, the second etching may be carried out before the first one.

The substrate 101 used comprises metallizations 117 on its upper surface.

In a second step, illustrated in FIG. 3B, a heat sink 105 is arranged in the lower portion of cavity 102. Shoulder 103 receives heat sink 105. Once arranged, heat sink 105 is integrally embedded in substrate 101. Heat sink 105 thus closes the lower end of cavity 102.

In a third step, illustrated by FIG. 3C, a bonding material 109 is deposited at the bottom of cavity 102, on heat sink 105. Bonding material 109 is for example solder paste or preferably thermal paste.

In a fourth step, illustrated by FIG. 3D, the IC chip 107 is deposited into cavity 102, on bonding material 109. A pressure may be applied to the IC chip on installing thereof to displace a portion of bonding material 109. Material 109 thus at least partly fills a space 111 between IC chip 107 and the walls of cavity 102. In the case of thermal paste, the pressure is thus applied before a paste curing sub-step. In the case of solder paste, the pressure is thus applied before a heating sub-step and thus before the paste cools down and hardens.

In a fifth step, not explicitly shown, the IC chip 107 is connected to substrate 101 by conductive wires 113 (see, FIG. 1). Conductive wires 113 connect contacts 115 located on a surface of IC chip 107 to connect them to metallizations 117 of the substrate. The obtained device is that illustrated in FIG. 1.

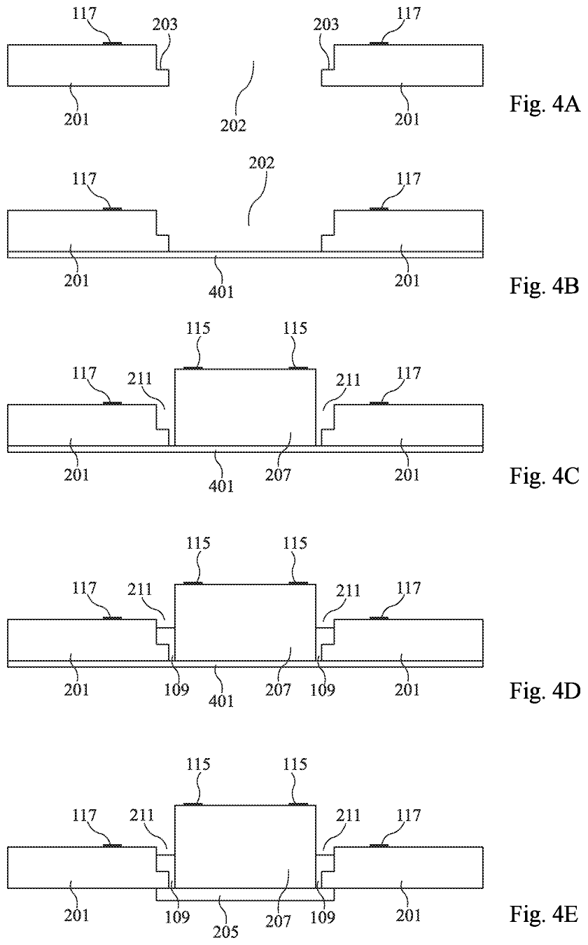

FIGS. 4A-4E show simplified cross-section views illustrating steps of implementation of a method of forming the electronic device of FIG. 2.

FIG. 4A illustrates a substrate 201, obtained after a step of etching a cavity 202 comprising a shoulder 203.

The step of etching cavity 202 and its shoulder 203 is carried out in two phases, like those shown for the embodiment of FIG. 1 and FIG. 3A except that the larger opening is on the opposite surface of the substrate. The substrate 201 used comprises metallizations 117 on its upper surface.

In a second step, illustrated by FIG. 4B, a film 401 is deposited on the lower surface of substrate 201, on the side of the smaller opening. Film 401 covers at least the lower end of cavity 202 and, preferably, the entire lower surface of substrate 201.

In a third step, illustrated by FIG. 4C, the IC chip 207 is arranged in cavity 202, on film 401. The IC chip comprises contact pads 115 on its upper surface. The function of film 401 is to ensure a temporary hold of IC chip 207 at a position where the bottom of the IC chip is coplanar with the rear face of the substrate.

In a fourth step, a bonding material 109 is deposited in a space 211, between IC chip 207 and the walls of cavity 202. Bonding material 109 is, for example, a solder paste or preferably thermal paste. In the case of thermal paste, the step comprises a paste curing sub-step. In the case of a solder paste, the step comprises a sub-step of heating of the assembly of the IC chip, substrate, and heat sink, to melt the paste, followed by a cooling step to enable the solder paste to solidify. The result is shown in FIG. 4D.

Once the thermal paste is dry or the solder paste has solidified, film 401 is removed, the IC chip being now bonded to the substrate. A heat sink 205 is then arranged, for example, glued, under IC chip 207 and substrate 201. In the shown example, the heat sink partially protrudes from the lower end of cavity 202 towards the outside thereof, such as illustrated by FIG. 4E.

IC chip 207 is then connected to substrate 201 by conductive wires 113 (not explicitly shown, see FIG. 2). Conductive wires 113 connect contacts 115 located on a surface of IC chip 207 to connect them to metallizations 117 of the substrate. The obtained device is that illustrated in FIG. 2.

An advantage of the described embodiments is that they efficiently dissipate the heat generated by the IC chip(s), while keeping small dimensions.

The embodiment described in relation with FIGS. 2 and 4A-4E has the advantage, over the embodiment described in relation with FIGS. 1 and 3A-3D, of simplifying the implementation of its forming method. Indeed, the heat sink is deposited on the substrate instead of being embedded therein. Such a simplicity gain is obtained at the cost of a slightly increased general bulk of the device.

Various embodiments and variations have been described. It will be understood by those skilled in the art that certain features of these various embodiments and variations may be combined, and other variations will occur to those skilled in the art. In particular, a same heat sink may combine the features of the heat sinks of the described embodiments and thus be able to close a plurality of cavities and be able to be partially embedded in the substrate.

Finally, the practical implementation of the described embodiments and variations is within the abilities of those skilled in the art based on the functional indications given hereabove. In particular, the selection of the bonding material to obtain the desired thermal and structural performance depends on the application.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

1. A method of forming an electronic device, comprising:
etching a cavity through a substrate;
arranging a heat sink to close one end of the cavity;
arranging an integrated circuit (IC) chip in the cavity of the substrate; and
connecting pads on an upper surface of the IC chip to metallizations on the substrate using conductive wires.

2. The method of claim 1, further comprising bonding the IC chip to at least one the substrate and/or to the heat sink using a deposited bonding material located between the IC chip and one or more of the walls of the cavity and the heat sink.

3. The method of claim 2, wherein the bonding material is thermal paste.

4. The method of claim 2, wherein the bonding material is solder paste.

5. The method of claim 1, further comprising embedding the heat sink in the substrate so that a rear surface of the device is planar on a side of the cavity closed by the heat sink.

6. The method of claim 1, further comprising mounting the heat sink external to the substrate on a rear surface of the substrate.

7. The method of claim 1, wherein the heat sink is made of copper.

8. The method of claim 7, wherein the heat sink is coated with a protection layer made of an alloy of nickel and of gold.

9. The method of claim 1, wherein etching the cavity comprises forming a shoulder in the cavity.

10. The method of claim 9, further comprising mounting the heat sink to the shoulder.

11. The method of claim 9, wherein forming the shoulder comprises positioning the shoulder to open on a side of the substrate opposite to another side of the substrate to which the heat sink is mounted.

12. The method of claim 1, further comprising:
depositing a film on a surface of the substrate to cover one end of the cavity;
installing the IC chip into the cavity on the film;
deposition of a bonding material in a space between walls of the cavity and the IC chip;
removing the film; and
bonding the heat sink under the IC chip.

13. An electronic device, comprising:
a substrate including a cavity extending through the substrate;
a heat sink closing one end of the cavity;
an integrated circuit (IC) chip installed in said cavity; and
a plurality of conductive of connection wires between pads on an upper surface of the IC chip and metallizations on the substrate.

14. The device of claim 13, further comprising a bonding material configured to bond the IC chip to one or more of the substrate and the heat sink.

15. The device of claim 14, wherein the bonding material is thermal paste.

16. The device of claim 14, wherein the bonding material is solder paste.

17. The device of claim 14, wherein at least a portion of bonding material fills a space between walls of the cavity and the IC chip.

18. The device of claim 14, wherein at least a portion of the bonding material is between the IC chip and the heat sink.

19. The device of claim 13, wherein the heat sink is embedded in the substrate so that a rear surface of the device is planar on a side of the cavity closed by the heat sink.

20. The device of claim 13, wherein the heat sink is mounted external to the substrate on a rear surface of the substrate.

21. The device of claim 13, wherein the heat sink is made of copper.

22. The device of claim 21, wherein the heat sink is coated with a protection layer made of an alloy of nickel and gold.

23. The device of claim 13, wherein the cavity has a shoulder.

24. The device of claim 23, wherein a surface of the heat sink is in contact with the shoulder.

25. The device of claim 23, wherein the shoulder is open on a side of the substrate opposite to another side of the substrate to which the heat sink is mounted.
